(19) United States
(12) Patent Application Publication
(10) Pub. No.: US 2014/0363971 A1
(43) Pub. Date: Dec. 11, 2014

(54) MANGANESE OXIDE FILM FORMING METHOD

(71) Applicant: Tokyo Electron Limited, Tokyo (JP)

(72) Inventor: Kenji Matsumoto, Nirasaki City (JP)

(73) Assignee: Tokyo Electron Limited, Tokyo (JP)

(21) Appl. No.: 14/294,349

(22) Filed: Jun. 3, 2014

(30) Foreign Application Priority Data
Jun. 5, 2013 (JP) 2013-118973

(51) Int. Cl. H01L 21/768; H01L 21/02

(52) U.S. Cl. CPC H01L 21/76843; H01L 21/02192; H01L 21/02271
USPC 438/653

(57) ABSTRACT

A manganese oxide film as a barrier film is formed on a structure in which a lower copper wiring layer is formed on a substrate, a silicon-containing oxide film as an interlayer film is formed on the lower copper wiring layer, and a recess is formed in the silicon-containing oxide film to reach the lower copper wiring layer. Further, this manganese oxide film is formed by an ALD process, and is controlled to have a thickness by adjusting the repetition number of times such that the manganese oxide film has a predetermined barrier property on the silicon-containing oxide film and copper buried in the recess has a preset resistance value on the exposed lower copper wiring layer.

### CROSS-REFERENCE TO RELATED APPLICATION

This application claims the benefit of Japanese Patent Application No. 2013-118973 filed on Jun. 5, 2013, the entire disclosures of which are incorporated herein by reference.

### TECHNICAL FIELD

The embodiments described herein pertain generally to a manganese oxide film forming method.

### BACKGROUND

With an increase of integration density of semiconductor devices, geometric dimensions of a semiconductor element and an internal wiring are being reduced more and more. To achieve high speed, high miniaturization and high integration of semiconductor devices, a multilayer wiring structure formed by embedding a metal wiring in an interlayer insulating film by a damascene method is widely used. Copper, which has low electromigration and low resistance, has been utilized as a material for the metal wiring. The multilayer wiring is formed through the processes of: forming a recess such as a trench or a via by removing an interlayer insulating film on a certain region until a wiring provided under the interlayer insulating film is exposed; and burying copper in the formed recess. Here, in order to suppress the copper from being diffused into the interlayer insulating film, the copper film is formed after a barrier film is formed.

Conventionally, such a barrier film is formed of Ta (tantalum), TaN (tantalum nitride), or the like by a PVD (Physical Vapor Deposition) method. When forming a thin barrier film by using the PVD method, however, miniaturization of a Cu wiring may accompany a degradation of step coverage in forming the film. For this reason, it has been proposed using a manganese oxide (MnOₓ) film, which has a high barrier property even with a small thickness, as the barrier film by using a CVD (Chemical Vapor Deposition) method or an ALD (Atomic Layer Deposition) method in which the step coverage is good. (see, for example, Patent Documents 1 to 4)
Patent Document 1: Japanese Patent Laid-open Publication No. 2008-300568
Patent Document 2: Japanese Patent Laid-open Publication No. 2010-021447
Patent document 3: Japanese Patent Laid-open Publication No. 2009-016782
Patent Document 4: Japanese Patent Laid-open Publication No. 2010-242187

When forming the manganese oxide film as the barrier film by the CVD method or the ALD method, a portion of the manganese oxide film formed on a silicon-containing oxide film serving as an interlayer insulating film is required to have a barrier property. However, a portion of the manganese oxide film in contact with an underlying copper wiring layer at the bottom of the via is not required to function as the barrier film. In this regard, there is a concern that the manganese oxide film may have an adverse influence on the copper wiring. Meanwhile, a manganese oxide film which has a high barrier property and, at the same time, does not have an adverse effect on the copper wiring layer is yet to be investigated.

### SUMMARY

In view of the foregoing problems, example embodiments provide a manganese oxide film forming method of forming a manganese oxide film having no adverse effect on a copper wiring layer and capable of maintaining a barrier property required as a barrier film for the copper wiring layer.

The present inventors have conducted researches repeatedly to solve the aforementioned problems and found out that a manganese oxide film can be densely formed in a uniform thickness on a silicon-containing oxide film on which the manganese oxide film needs to function as a barrier film, whereas the manganese oxide film becomes a discontinuous crystalline manganese oxide film having a non-uniform thickness on a copper wiring layer. As a result, a via resistance may be increased in an actual semiconductor device.

An example embodiment is based on these observations. In one example embodiment, a manganese oxide film forming method is to form a manganese oxide film as a barrier film on a structure in which a lower copper wiring layer is formed on a substrate, a silicon-containing oxide film as an interlayer film is formed on the lower copper wiring layer, and a recess is formed in the silicon-containing oxide film to reach the lower copper wiring layer. Further, the manganese oxide film is formed by an ALD process in which an adsorbing process of supplying and adsorbing a manganese compound gas onto the structure and a reacting process of supplying an oxygen-containing gas and reacting the adsorbed manganese compound gas with the oxygen-containing gas are repeatedly performed in a preset repetition number of times. Furthermore, the manganese oxide film is controlled to have a thickness by adjusting the repetition number of times such that the manganese oxide film has a predetermined barrier property on the silicon-containing oxide film and copper buried in the recess has a preset resistance value on the exposed lower copper wiring layer.

The repetition number of times may be adjusted such that the thickness of the manganese oxide film on the silicon-containing oxide film has a range from about 1 nm to about 3.5 nm. Further, the thickness of the manganese oxide film may be a value converted from an atom number of manganese.

The thickness of the manganese oxide film may be equivalent to a value that allows a flat band voltage shift to be equal to or higher than about −0.2 V and equal to or lower than about 0.2 V on the silicon-containing oxide film and that allows an increment of the resistance value to be within about 1Ω on the lower copper wiring layer.

The manganese compound gas may be at least one selected from the group consisting of a cyclopentadienyl-based manganese compound, a carbonyl-based manganese compound, a β-diketone-based manganese compound, an amidinate-based manganese compound and an amide amino alkane-based manganese compound.

The oxygen-containing gas may be at least one selected from the group consisting of H₂O, N₂O, NO₂, NO, O₂, O₃, H₂O₂, CO, CO₂, alcohol, aldehyde, carboxylic acid, carboxylic acid anhydride, ester, organic ammonium salt, organic amine salt, organic amide, organic hydrazide.

At least a part of the manganese oxide film on the silicon-containing oxide film may be silicified.

In accordance with the example embodiments, it is possible to obtain a manganese oxide film having a higher barrier property capable of suppressing copper diffusion without having an adverse effect on a copper wiring layer by adjusting an increase of a resistance of a copper wiring to a tolerance value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart for a manganese oxide film forming method in accordance with an example embodiment;

FIG. 2A and FIG. 2B are cross sectional views for describing the manganese oxide film forming method in accordance with the example embodiment;

FIG. 3 is a cross sectional view illustrating a semiconductor device manufactured by forming an upper copper wiring layer after forming a manganese oxide film;

FIG. 4 provides a TEM image showing a cross sectional view of a portion of the manganese oxide film formed between a silicon-containing oxide film and the upper copper wiring layer;

FIG. 5 is a graph showing a relationship between a thickness of the manganese oxide film and a flat band voltage shift;

FIG. 6 is a TEM image showing a cross sectional view of a portion of the manganese oxide film formed on a lower copper wiring layer;

FIG. 7 is a graph showing cumulative probability distribution of via resistance values in a sample dual damascene structure having a via chain in which about 26000 vias having a diameter of about 80 nm are arranged;

FIG. 8 is a diagram showing, based on the data of FIG. 7, a relationship between the number of ALD cycles in forming the manganese oxide film and the via resistance;

FIG. 9 is a graph showing, based on the data of FIG. 8, a relationship between a manganese oxide film thickness corresponding to the number of ALD cycles and the via resistance value caused by the manganese oxide film;

FIG. 10 is a graph showing a relationship between the number of ALD cycles and the manganese oxide film thickness when forming manganese oxide films at about 130° C. by using a TEOS-SiO₂ film and a low-k (SiOCH) film as the underlying silicon-containing oxide film and when performing a hydrophilic treatment on the low-k film;

FIG. 11 is a graph showing a relationship between the number of ALD cycles and the manganese oxide film thickness when the manganese oxide film is formed on the TEOS-SiO₂ film within a film forming temperature ranging from about 125° C. to about 200° C.;

FIG. 12 is a diagram plotting the data of FIG. 11 in relation to a film forming temperature and the manganese oxide film thickness per a single cycle;

FIG. 13 is a graph showing a relationship between the film forming temperature and the number of ALD cycles required to deposit the manganese oxide film having a thickness of about 1 nm;

FIG. 14 is a plane view illustrating an example film forming system for manufacturing a semiconductor device including the manganese oxide film in accordance with the example embodiment; and

FIG. 15 is a cross sectional view illustrating a manganese oxide film forming apparatus provided in the film forming system of FIG. 14.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

<Formation of Manganese Oxide Film>

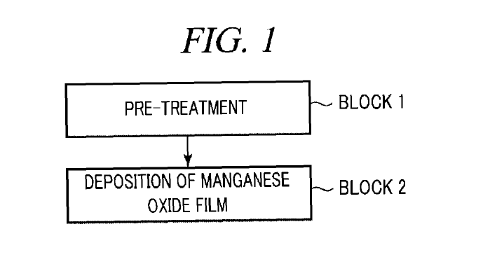

FIG. 1 is a flowchart for describing a manganese oxide film forming method in accordance with an example embodiment. In the present example embodiment, the manganese oxide film serves as a barrier film of a copper wiring layer in a semiconductor device including a multilayer copper wiring.

(Base Body for Forming Manganese Oxide Film)

First, a base body for forming the manganese oxide film will be explained. Here, the description of processes of manufacturing a transistor will be omitted.

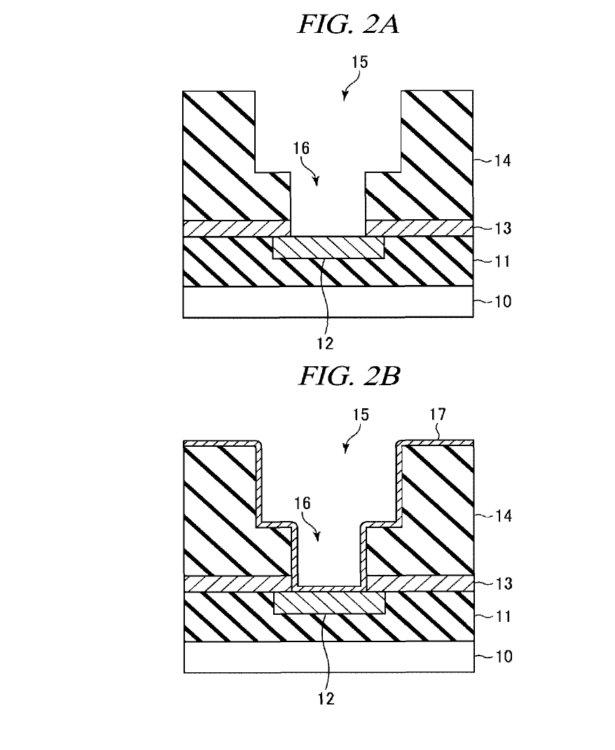

As shown in FIG. 2A, an insulating film 11 is formed on a semiconductor substrate 10 such as a silicon substrate, and an lower copper wiring layer 12 is formed in a surface of the insulating film 11. On this structure, a diffusion barrier film 13 such as SiCN and an interlayer insulating film 14 are deposited, and then, a trench 15 as a wiring groove and a via 16 as a connection hole are formed in the interlayer insulating film 14 and the diffusion barrier film 13 as a recess. The lower copper wiring layer 12 is exposed at a bottom of the via 16.

A silicon-containing oxide film may be used as the insulating film 11 and the interlayer insulating film 14. The silicon-containing oxide film may be, but not limited to, a SiO₂ film (TEOS-SiO₂ film) formed by a CVD method using a tetraethoxysilane (TEOS) gas as a source gas. Further, the silicon-containing oxide film may be a silicon-containing oxide film (low-k film), such as SiOC or SiOCH, having a relative permittivity lower than that of SiO₂. As such a low-k film, a porous low-k film having pores may be used. The trench 15 and the via 16 may be formed by a photolithography process and a dry etching process.

(Process of Block 1 (Pre-Treatment))

Subsequently, as a process of block 1 in FIG. 1, a pre-treatment is performed on this base body. The pre-treatment may include a degassing process, a cleaning process, or the like. Through this pre-treatment, the insides of the trench 15 and the via 16 are cleaned. The cleaning process may be implemented by, but not limited to, a H₂ annealing process, a H₂ plasma process, an Ar plasma process, a dry cleaning process using organic acid, or the like.

Further, the degassing process through the heating may be performed in an inert gas atmosphere such as N₂, Ar or He at a temperature ranging from, e.g., about 250° C. to about 400° C. and under a pressure ranging from, e.g., about 13 Pa to about 2670 Pa for a processing time ranging from, e.g., about 30 seconds to about 300 seconds. By way of non-limiting example, the degassing process may be performed in the Ar atmosphere at the temperature of about 300° C. and under the pressure of about 1330 Pa for the processing time of about 120 seconds.

Further, a naturally oxidized copper (formed on a surface of the copper exposed at the bottom of the via 16) may be reduced to be removed by the H₂ annealing process in a H₂ atmosphere (to which an inert gas such as N₂, Ar or He may be further added and in which a H₂ concentration may be from about 1 vol % to about 100 vol %) at a wafer temperature ranging from, e.g., about 250° C. to about 400° C. and under a pressure ranging from, e.g., about 13 Pa to about 2670 Pa for a processing time ranging from, e.g., about 30 seconds to about 300 seconds. Desirably, by way of non-limiting example, the naturally oxidized copper may be reduced to be removed in a forming gas atmosphere (about 3% of H₂ and about 97% of Ar) at a wafer temperature of about 300° C. and under a pressure of about 1330 Pa for the processing time of about 120 seconds.

A surface of the silicon-containing oxide film forming the interlayer insulating film 14 may have a hydrophobic property. Especially, when the silicon-containing oxide film is a low-k film such as SiOC or SiOCH, since methyl groups, which are hydrophobic groups, are arranged on the surface of the silicon-containing oxide film, the hydrophobic property of the surface of the silicon-containing oxide film may become higher. When the surface is hydrophobic, an oxygen-containing gas (to be described later, especially, H₂O) introduced when forming a manganese oxide film is difficult to be adsorbed onto that surface, so that it is difficult to form a continuously smooth thin film thereon. In such a case, it may be desirable to perform a surface modification process (hydrophilic treatment) of the interlayer insulating film 14 as a pre-treatment. This surface modification process may be performed by exposing the surface of the interlayer insulating film 14 to plasma. The plasma can be generated by using various kinds of gases. By way of non-limiting example, a gas containing hydrogen (H), carbon (C), nitrogen (N) or oxygen (O) (e.g., one of a H₂ gas, a CO gas, a CO₂ gas, a CH₄ gas, a N₂ gas, a NH₃ gas, a H₂O gas, an O₂ gas, an O₃ gas, a NO gas, a N₂O gas and a NO₂ gas, or a combination thereof) may be used. Further, a rare gas such as He or Ar may also be added in order to facilitate plasma ignition. Processing may proceed from block 1 to block 2.

(Process of Block 2 (Deposition of Manganese Oxide Film))

Subsequently, a deposition process of a manganese oxide film (MnOₓ film) is performed as a process of block 2 in FIG. 1. At block 2, as depicted in FIG. 2B, a manganese oxide film 17 serving as a barrier film is formed on the interlayer insulating film 14 and on inner walls of the trench 15 and the via 16. The manganese oxide film 17 can be formed by an ALD method using a manganese compound gas and an oxygen-containing gas.

Further, manganese oxides may include those having multiple numbers of valences such as MnO, Mn₃O₄, Mn₂O₃, MnO₂. Thus, hereinafter, the manganese oxide may be represented by MnOₓ (1≦x≦2).

Examples of a source material for the manganese oxide used in the process at block 2, i.e., a manganese compound used as a precursor for the manganese oxide may be listed as follows.

Cyclopentadienyl-based manganese compound

Carbonyl-based manganese compound

β-diketone-based manganese compound

Amidinate-based manganese compound

Amide amino alkane-based manganese compound

By selecting a gas containing one of these manganese compounds; or selecting a gas containing multiple manganese compounds, it is possible to form the manganese oxide film 17.

An example of the cyclopentadienyl-based manganese compound may be bis (alkyl cyclopentadienyl) manganese represented by a general formula of Mn(RC₅H₄)₂.

Further, examples of the carbonyl-based manganese compound may be as follows.

Dimanganese decacarbonyl (Mn₂(CO)₁₀)
Methylcyclopentadienyl manganese tricarbonyl ((CH₃C₅H₄)Mn(CO)₃)
Cyclopentadienyl tricarbonyl manganese ((C₅H₅)Mn(CO)₃)
Methyl pentacarbonyl manganese ((CH₃)Mn(CO)₅)
3-(t-BuAllyl)Mn(CO)₄

Further, examples of the β-diketone-based manganese compound may be as follows.

Bis (dipivaloylmethanate) manganese (Mn(C₁₁H₁₉O₂)₂)

Tris (dipivaloylmethanate) manganese (Mn(C₁₁H₁₉O₂)₃)

Bis (pentanedione) manganese (Mn(C₅H₇O₂)₃)

Tris (pentanedione) manganese (Mn(C₅H₇O₂)₃)

Bis (hexafluoroacetyl) manganese (Mn(C₅HF₆O₂)₂)

Tris (hexafluoroacetyl) manganese (Mn(C₅HF₆O₂)₃)

Further, an example of the amidinate-based manganese compound may be, but not limited to, bis(N,N′-dialkylacetamidinate) manganese represented by a general formula of Mn(R¹N—CR³—NR²)₂ described in U.S. Patent Application Publication No. US2009/0263965 A1.

Further, an example of the amide amino alkane-based manganese compound may be, but not limited to, bis(N,N′-alkylamid-2-dialkylaminoalkane) manganese represented by a general formula of Mn(R¹N—Z—NR²₂)₂ described in International Publication No. WO2012/060428. Here, “R, R¹, R², R³” in the general formulas denote an alkyl group represented by CₙH₂ₙ₊₁ (n is an integer equal to or larger than 0), and “Z” denotes an alkylen group represented by —C₁₁H₂ₙ— (n is an integer equal to or larger than 0).

Further, the oxygen-containing gas may be, by way of non-limiting example, H₂O, N₂O, NO₂, NO, O₂, O₃, H₂O₂, CO, CO₂, alcohol, aldehyde, carboxylic acid, carboxylic acid anhydride, ester, organic ammonium salt, organic amine salt, organic amide, organic hydrazide, etc. Further, it may be also possible to use a combination of these oxygen-containing gases. A material which is a liquid phase at a room temperature may be supplied into a processing chamber in a gas or vapor state by being heated and vaporized, for example.

Further, thermal decomposition temperatures of the manganese compound gases may be as follows.
about 250° C. to about 300° C. when using an amide amino alkane-based manganese compound
about 350° C. to about 400° C. when using an amidinate-based manganese compound
about 400° C. to about 450° C. when using (EtCp)₂Mn as a cyclopentadienyl-based manganese compound
about 450° C. to about 500° C. when using MeCpMn(CO)₃ as a carbonyl-based manganese compound

However, by reacting these manganese compound gases with an oxygen-containing gas such as H₂O, the thermal decomposition of the manganese compound gases may occur at temperatures lower than the above-specified temperatures, so that a manganese oxide film can be formed. In consideration of this, when forming a manganese oxide film by the ALD method, it may be desirable to set a film forming temperature to be equal to or lower than the thermal decomposition temperature of the manganese compound gas. By way of example, when using the amide amino alkane-based manganese compound, it may be desirable that the film forming temperature is set to be equal to or lower than about 250° C. If the film is formed at a temperature equal to or higher than the thermal decomposition temperature of the manganese compound gas, a film forming reaction may occur even when no oxygen-containing gas is introduced. In such a case, not an ALD film formation but a CVD film formation may be performed. In the ALD film formation, the oxygen-containing gas such as H₂O needs to be adsorbed to and stay on the base body. Further, at a high temperature range, desorption may occur more frequently than adsorption, so that a film forming rate is decreased. Thus, it may be desirable to set the film forming temperature to be lower than a degassing temperature. In this aspect, it may be desirable that the film forming temperature is equal to or lower than about 250° C.

Further, by using plasma, it may be possible to form the film at a lower temperature. Moreover, by using the plasma, precursors may be variously selected. Among the aforementioned manganese compound gases, an amide amino alkane-based manganese compound capable of forming a film at a comparatively lower temperature may be practically suitable.

When forming a manganese oxide film by the ALD method, a first process of supplying a manganese compound gas into the processing chamber, in which a process is performed, and adsorbing the manganese compound gas onto the base body; a second process of purging; and a third process of supplying an oxygen-containing gas into the processing chamber and forming a manganese oxide film through a chemical reaction between the manganese compound adsorbed on the base body and the oxygen-containing gas may be alternately repeated a preset number of times in this sequence. At this time, a thickness of the manganese oxide film can be controlled by adjusting the number of repetition (i.e., the number of ALD cycles) of these processes. A gas flow rate and a pressure may be appropriately set.

<Semiconductor Device Including Manganese Oxide Film>

After the manganese oxide film 17 having a required thickness is formed through the above-described processes, an annealing process may be performed in a reducing atmosphere when necessary, so that at least a part of the manganese oxide film 17 is silicified through a reaction between the manganese oxide film 17 and the silicon-containing oxide film as the underlying interlayer insulating film 14.

Thereafter, an upper copper wiring layer 18 is formed, as depicted in FIG. 3. The upper copper wiring layer 18 may be formed by performing copper plating after forming a copper seed through the PVD method, or may be formed only by the PVD method. The copper plating may be electroplating or electroless plating. Alternatively, the upper copper wiring layer 18 may also be formed by the CVD method, the ALD method, the supercritical CO₂ method, or the like. After the upper copper wiring layer 18 is formed, a planarization process thereof may be performed by the CMP when necessary. By repeating these processes, it is possible to manufacture a semiconductor device having a multilayer wiring of a dual damascene structure.

Further, the aforementioned annealing process may be omitted, and the manganese oxide film 17 may be silicified by performing an annealing process after forming the upper copper wiring layer 18. Further, depending on a process oat forming the upper copper wiring layer 18, the manganese oxide film 17 may be silicified by heat generated when forming the upper copper wiring layer. Further, the manganese oxide film may become silicified by heat applied thereto when depositing an interlayer insulating film or a diffusion barrier film on the manganese oxide film by the CVD method.

In the semiconductor device having such a dual damascene structure, the manganese oxide film 17 serves as the diffusion barrier film between the silicon-containing oxide film as the interlayer insulating film 14 and the upper copper wiring layer 18. In order to obtain the function of the barrier film effectively, it may be desirable to perform the annealing process in a reducing atmosphere, so that at least a part of the manganese oxide film may be silicified through the reaction between the manganese oxide film and the underlying silicon-containing oxide film. Manganese silicate (MnSiOₓ) formed at this time is amorphous, and has a high barrier property. Besides the improvement of the barrier property, other effects such as a reduction of a volume of the diffusion barrier film (a cross section of the upper copper wiring can be enlarged as much as the volume of the diffusion barrier film is reduced), improvement of adhesivity, stabilization of film composition may be obtained through the silicification process thereof.

<Relationship Between Manganese Oxide Film Thickness and Barrier Property)

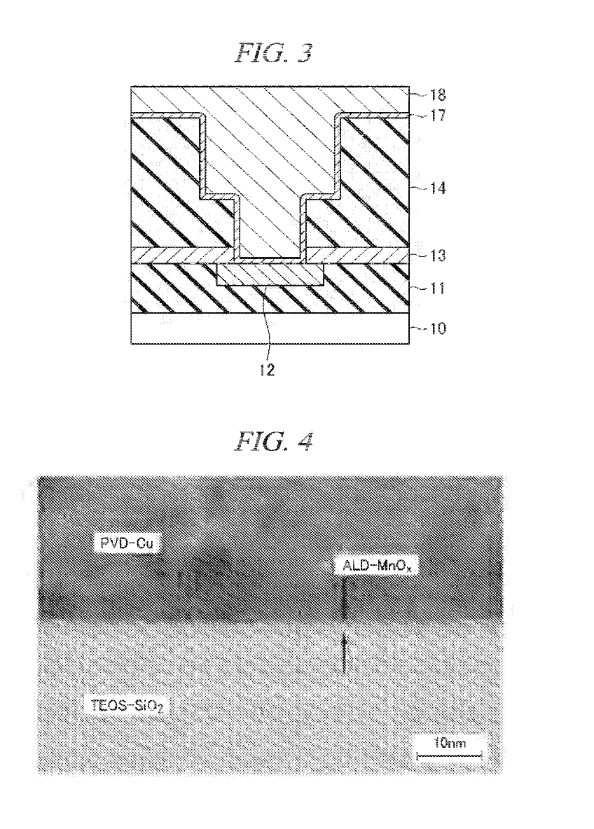

When the upper copper wiring layer is formed, the manganese oxide film serves as a barrier film between the silicon-containing oxide film and the upper copper wiring layer, and a cross sectional state of that portion of the manganese oxide film is as shown in a TEM (Transmission Electron Microscopy) image of FIG. 4. Here, a sample is prepared by forming a manganese oxide film on a TEOS-SiO₂ film at a temperature of about 200° C. through 25 cycles by the ALD method; forming a PVD-Cu film thereon; and performing the annealing process at about 400° C. in a hydrogen atmosphere for about 1 hour. As can be seen from FIG. 4, the manganese oxide film exists as a continuous film having a dense and uniform thickness of about 2.0 nm at an interface between the silicon-containing oxide film and an upper copper wiring layer. Since the manganese oxide film exists as such a continuous film of a dense and uniform thickness, it is possible to improve the high barrier property of suppressing copper diffusion into the silicon-containing oxide film from the upper copper wiring layer. If the manganese silicate is formed, the barrier property can be further improved because the manganese silicate becomes amorphous without having a grain boundary.

The diffusion barrier property against the copper can be evaluated by a flat band voltage shift in a capacitance-voltage measurement performed after BTS (a stress of a preset electric field and a preset temperature is applied). If the flat band voltage shift is near about zero (equal to or higher than about −0.2 V and equal to or lower than about 0.2 V), it may be determined that the barrier property is fine.

The barrier property can be improved by increasing the thickness of the manganese oxide film. Thus, the thickness of the manganese oxide film needs to be set to be equal to or larger than a value that allows the flat band voltage shift to have a certain value close to zero. At this time, since the thickness of the manganese oxide film varies depending on a silicification ratio, a valence of the manganese oxide, a film density, and the like, it may be desirable to evaluate a film thickness converted from the atom number of Mn. By way of example, the atom number of Mn may be calculated by XRF (X-ray Fluorescence), and by converting the calculated value into, e.g., MnO, it is possible to calculate a thickness of MnO as a manganese oxide film.

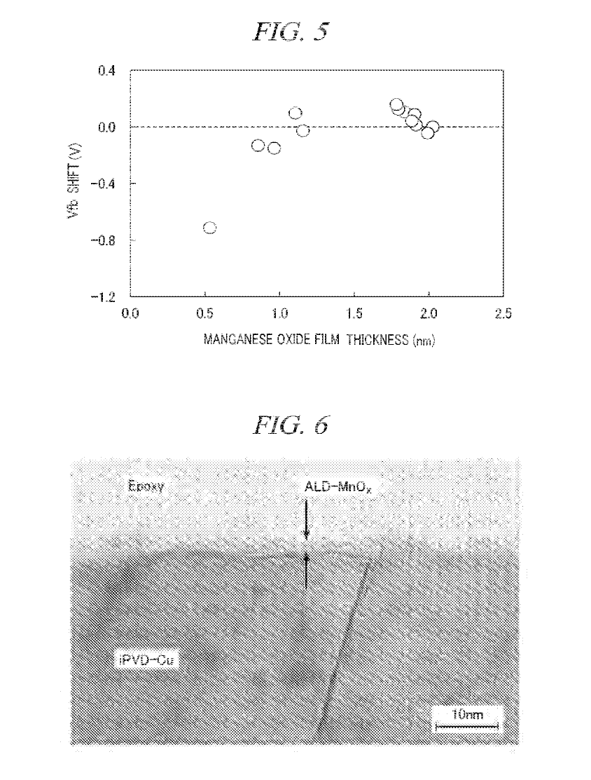

FIG. 5 is a diagram showing a relationship between a thickness of a manganese oxide (MnO) film calculated as described above and a flat band voltage shift. A horizontal axis represents the thickness of the manganese oxide (MnO) film, and a vertical axis represents the flat band voltage shift. Here, a sample is prepared by forming a thermal SiO₂ film and a TEOS-SiO₂ film on an n-type silicon substrate; forming thereon a manganese oxide (MnOₓ) film by the ALD method at a temperature of about 130° C.; depositing a copper film and forming a pattern for a test; performing an annealing process in a hydrogen atmosphere at a temperature of about 400° C. for about 30 minutes; and performing BTS. Further, the thickness of the manganese oxide film is varied by adjusting the number of ALD cycles.

As can be seen from FIG. 5, if the converted thickness of the manganese oxide film is equal to or larger than about 1 nm, a higher barrier property can be obtained. Thus, in order to obtain a higher barrier property, the number of ALD cycles for the manganese oxide film needs to be set to obtain a film thickness equal to or larger than about 1 nm.

<Relationship Between Manganese Oxide Film Thickness and Via Resistance>

Meanwhile, the manganese oxide film need not serve as a barrier film on a surface of the lower copper wiring layer at the bottom of the via. Further, the manganese oxide has a relatively high resistance value. Accordingly, if the thickness of the manganese oxide film exceeds a certain value, a via resistance may be increased when the trench and the via are buried by forming the upper copper wiring layer. To elaborate, as can be seen from a cross sectional TEM image of FIG. 6, if a manganese oxide film is deposited on a surface of the lower copper wiring layer, a discontinuous crystalline manganese oxide film having a thickness of about 1.5 nm to about 6 nm is formed, and this discontinuous film causes an increase of a via resistance. Further, FIG. 6 indicates a case of forming a manganese oxide film on a lower copper wiring layer through 10 cycles of the ALD process at a temperature of about 125° C. by the ALD method.

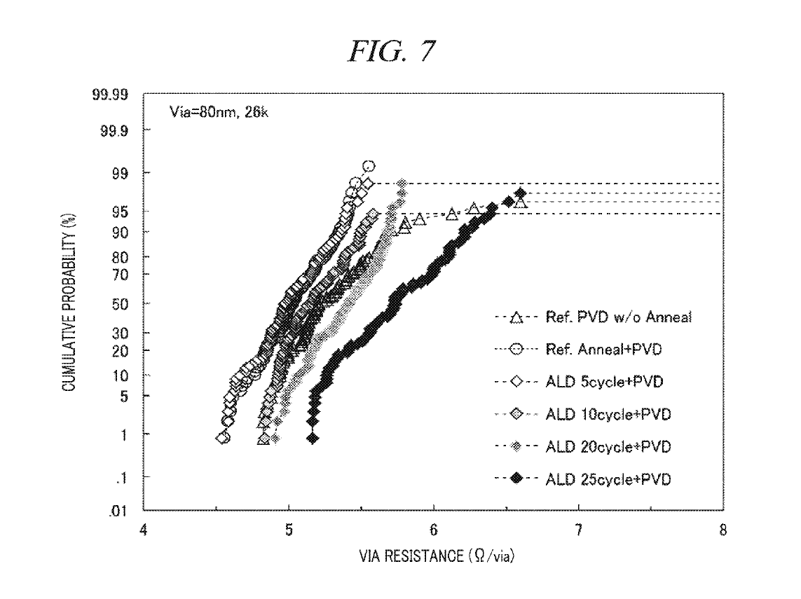

A result of actually investigating an effect of a manganese oxide film, which is formed on a lower copper wiring layer, upon a via resistance will be explained. FIG. 7 is a graph showing a cumulative probability distribution of via resistance values measured by using samples of a dual damascene structure having a via chain in which about 26000 vias having a diameter of about 80 nm are arranged. In FIG. 7, a resistance value per via is provided. Here, to process the samples under the conventional CMP conditions, the samples are prepared by forming Ta/TaN films, which are currently used as standard diffusion barrier films, through the PVD method on a manganese oxide film formed by the ALD method; and by forming an upper copper wiring layer on the Ta/TaN film. As for the processing conditions for forming the manganese oxide film by the ALD, a film forming temperature is set to be about 130° C., and the number of ALD cycles is set to be in the range from about 0 to about 25. On one of two references, the ALD process is not performed. Further, on the other reference, an annealing process is performed at about 130° C. for about 10 minutes to apply the same thermal history as that in the film formation by the ALD method. In comparison of these two references, a via resistance of the sample undergone through the annealing process is found to be lower than that of the other reference. This is because Cu crystals of the copper wiring layer are grown through the annealing process. As shown in FIG. 7, as the number of ALD cycles in forming the manganese oxide film increases, the via resistance is also found to increase. This is because a thickness of the manganese oxide film deposited on the lower copper wiring layer also increases with the rise of the number of ALD cycles.

An open fault accompanying a phenomenon that a via resistance value becomes infinite is observed in most samples, although the frequency thereof is not high. However, in view of the fact that the open fault occurs even in the reference samples, the occurrence of the open fault may be irrelevant to forming the manganese oxide film by the ALD method.

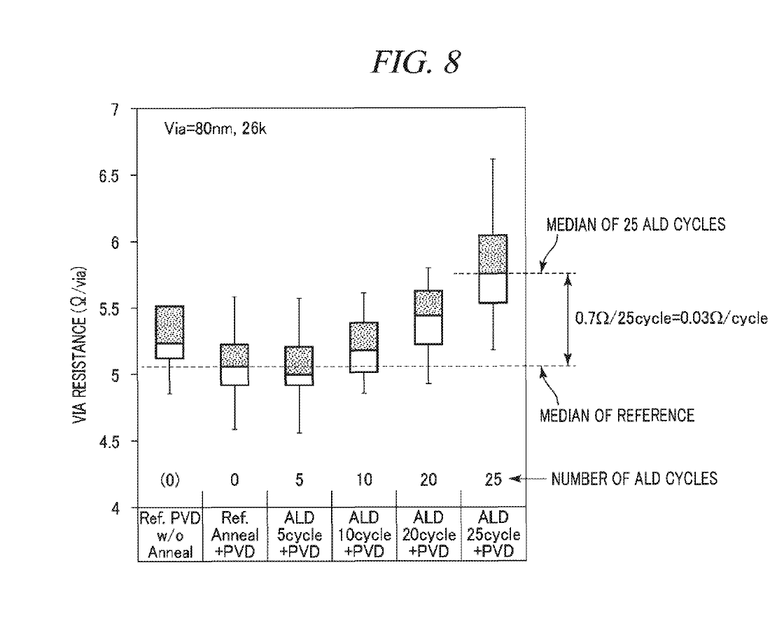

FIG. 8 is a diagram that organizes the data of FIG. 7. In FIG. 8, a horizontal axis represents the number of ALD cycles in forming the manganese oxide film, and a vertical axis indicates the via resistance value. Further, FIG. 8 also shows a range of non-uniformity of via resistances at respective numbers of ALD cycles and medians thereof. Dashed lines indicate a median of the reference (undergone through the annealing process) and a median of a sample manufactured by performing 25 cycles of ALD process, respectively. From this diagram, it is estimated that a difference between a via resistance value of the reference undergone through the annealing process and a via resistance value of the sample manufactured through 25 cycles of ALD process is about 0.7Ω, and an increment of the via resistance per a single cycle is about 0.03Ω. Further, each sample of the dual damascene structure having the via chain used in this experiment has a film structure in which Ta/TaN films are stacked on top of the manganese oxide film formed by the ALD method as described above, and in the obtained experiment data of the via resistances, resistance of the Ta/TaN film is added. Here, though not shown, a cross sectional TEM image of a via structure is investigated. A diameter of an opening at the bottom of a via is narrowed to be about 60 nm. Further, in the stacked Ta/TaN film, a thickness of the Ta film and the thickness of the TaN film are about 1.9 nm, respectively. Since resistivities of Ta and TaN are about 135 nΩ·m and about 1360 nΩ·m, respectively, a combined resistance of the Ta/TaN film in a single via is estimated to about 1.00Ω. Essentially, since the Ta/TaN film need not be deposited, a value obtained by subtracting about 1Ω from this obtained resistance value becomes a via resistance when forming a diffusion barrier film only with the manganese oxide film formed by the ALD method.

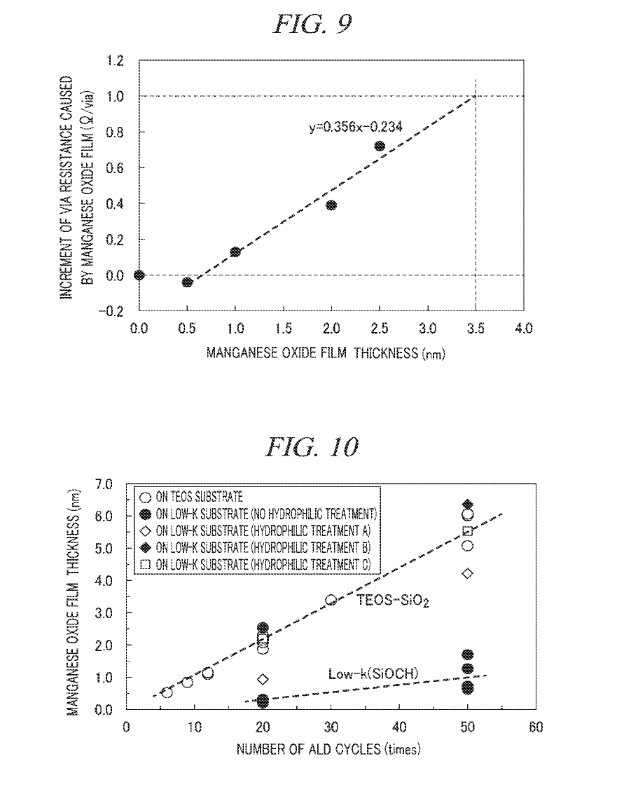

FIG. 9 is a graph showing a relationship between a thickness of a manganese oxide film corresponding to the number of ALD cycles and an increment of a via resistance caused by the manganese oxide film, based on the data of FIG. 8. In FIG. 9, a horizontal axis represents a thickness of a manganese oxide film corresponding to the number of ALD cycles, and a vertical axis indicates an increment of a via resistance. Since a discontinuous and non-uniform manganese oxide film is formed on a copper wiring layer, a thickness of a manganese oxide film measured on an interlayer insulating film is used here. Further, a manganese oxide film formed through a single ALD cycle is analyzed by XRF, and a thickness of the manganese oxide film (MnO) is calculated by being converted from the calculated number of Mn atoms. As a result, a thickness of the manganese oxide film is found to be about 0.1 nm when performing the single ALD cycle and about 1 nm when performing 10 ALD cycles. A tolerance value of a via resistance is the same as that when using Ta/TaN films which are currently used as the standard diffusion barrier film. Thus, if a via resistance of about 1.0Ω/via is set as a threshold value, a via resistance would be allowable if the thickness of the manganese oxide film is equal to or smaller than about 3.5 nm. Thus, under the present conditions, the number of ALD cycles needs to be set to be 35 times or below.

<Desirable Thickness of Manganese Oxide Film>

As stated above, desirably, the thickness of the manganese oxide film needs to be equal to or larger than about 1 nm in the view of obtaining a barrier property against Cu within a tolerance value and needs to be equal to or smaller than about 3.5 nm in the view of obtaining a via resistance on the copper wiring layer within a tolerance value. To meet both of these requirements, it may be desirable that the thickness of the manganese oxide film ranges from about 1 nm to about 3.5 nm. By setting the thickness of the manganese oxide film to be in the range from about 1 nm to about 3.5 nm, it may be possible to set a via resistance to be in a tolerance range while obtaining a fine barrier property. Especially, by setting the thickness of the manganese oxide film to be about 1 nm, it may be possible to obtain a via resistance lower than a reference while maintaining a fine barrier property. At this time, desirably, the thickness of the manganese oxide film may be a thickness on an interlayer insulating film, as described above, to which a correspondence between the number of ALD cycles and a film thickness is applied. Further, it may be also desirable that the thickness is a film thickness converted from the number of Mn atoms not to be affected by the silicification process or the like.

<Relationship Between Number of ALD Cycles and Film Thickness>

The thickness of the manganese oxide film formed by the ALD method may increase, under the same conditions, as the number of ALD cycles increases. Thus, the thickness of the manganese oxide film can be controlled by adjusting the number of ALD cycles. However, if a surface state of the silicon-containing film as the interlayer insulating film or a film forming temperature is different, an increasing rate may be differed.

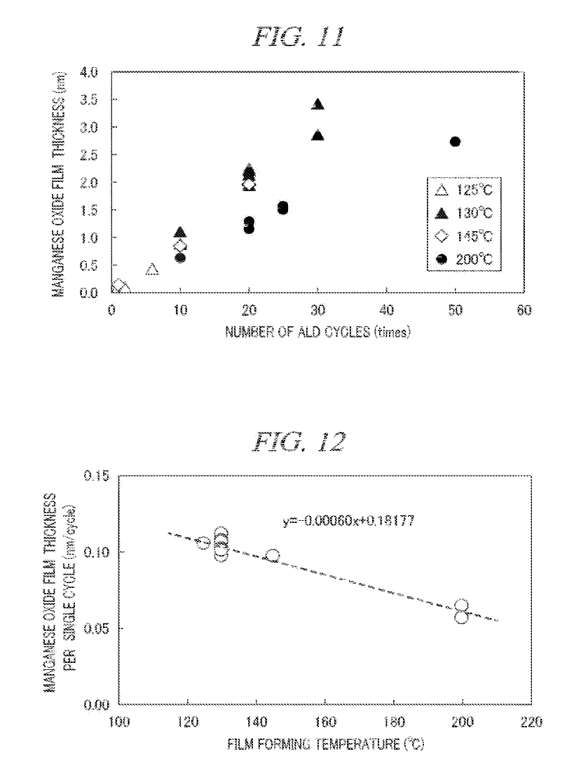

FIG. 10 is a graph showing a relationship between the number of ALD cycles in forming a manganese oxide film and a thickness of the manganese oxide film when forming the manganese oxide film at a temperature of about 130° C. by using a TEOS-SiO₂ film and low-k film (SiOCH) as the underlying silicon-containing film. For the low-k film, cases of performing surface modification processes (hydrophilic treatments) are also provided. The hydrophilic treatments include a hydrogen radical treatment (hydrophilic treatment A) by remote plasma at about 1000 W (low power), a hydrogen radical treatment (hydrophilic treatment B) by remote plasma at about 2500 W (high power) and an oxygen-based plasma treatment (hydrophilic treatment C). The thickness of the manganese oxide film is converted from the number of Mn atoms measured by using XRF.

As can be seen from FIG. 10, under the respective conditions, the thickness of the manganese oxide film increases in proportion to the number of the ALD cycles, and it is possible to control the thickness of the manganese oxide film by adjusting the number of ALD cycles. However, film forming rates are found to be different depending on the kinds of the underlying layers. When the underlying layer is the TEOS-SiO₂ film, the thickness of the manganese oxide film can be set to be about 1 nm through 10 cycles of ALD process, whereas when the underlying layer is the low-k film, the number of the ALD cycles needs to be 50 times in order to obtain a film thickness of about 1 nm, since the surface of the low-k film is hydrophobic. According to the present example embodiment, by performing an appropriate hydrophilic treatment, it may be possible to reduce the number of ALD cycles to about 10 times, as in the case of the TEOS-SiO₂ film.

FIG. 11 is a graph showing a relationship between the number of ALD cycles and a thickness of a manganese oxide film when forming the manganese oxide film on a TEOS-SiO₂ film at a film forming temperature ranging from about 125° C. to about 200° C. As can be seen from this graph, a film forming rate varies depending on the film forming temperature. However, it is also found out that even if the film forming temperature varies, it is still possible to control the thickness of the manganese oxide film by adjusting the number of ALD cycles at a same temperature.

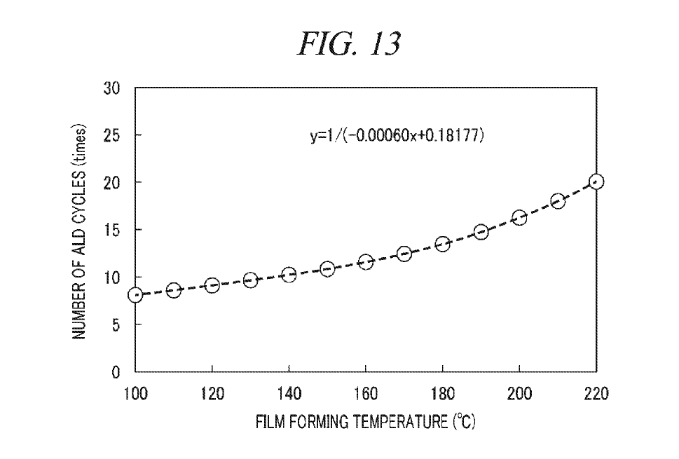

FIG. 12 is a graph re-plotting the data of FIG. 11 in relation to a film forming temperature and a thickness of the manganese oxide film per a single cycle. As can be seen from this graph, as the film forming temperature increases, a film forming rate decreases. FIG. 13 shows a relationship between a film forming temperature and the number of ALD cycles required to deposit a manganese oxide film having a thickness of about 1 nm. As can be seen from this graph, as the film forming temperature increases, the number of the required ALD cycles also increases.

As discussed above, since a relationship between a thickness of a manganese oxide film and the required number of ALD cycles in forming the manganese oxide film is different depending on film forming conditions, the number of ALD cycles for obtaining a required thickness of the manganese oxide film needs to be set appropriately depending on the film forming conditions.

<Film Forming System>

Now, an example film forming system for manufacturing a semiconductor device including a manganese oxide film in accordance with the present example embodiment will be described.

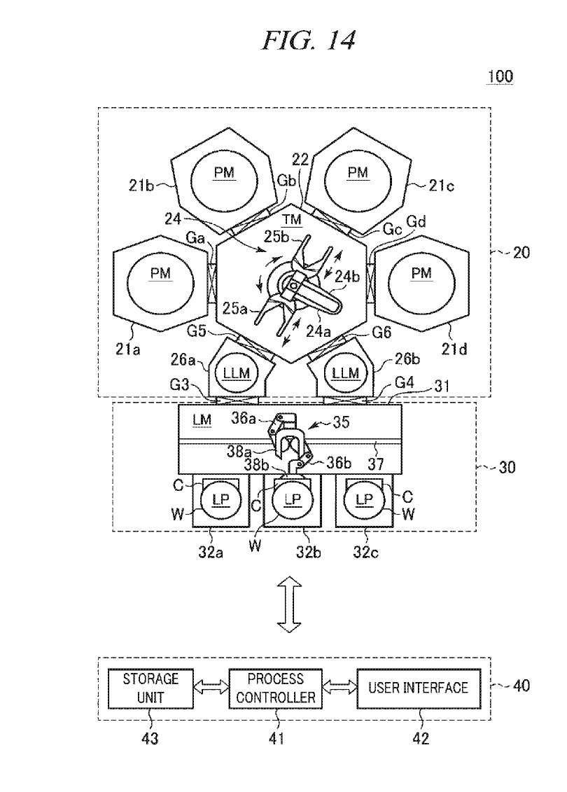

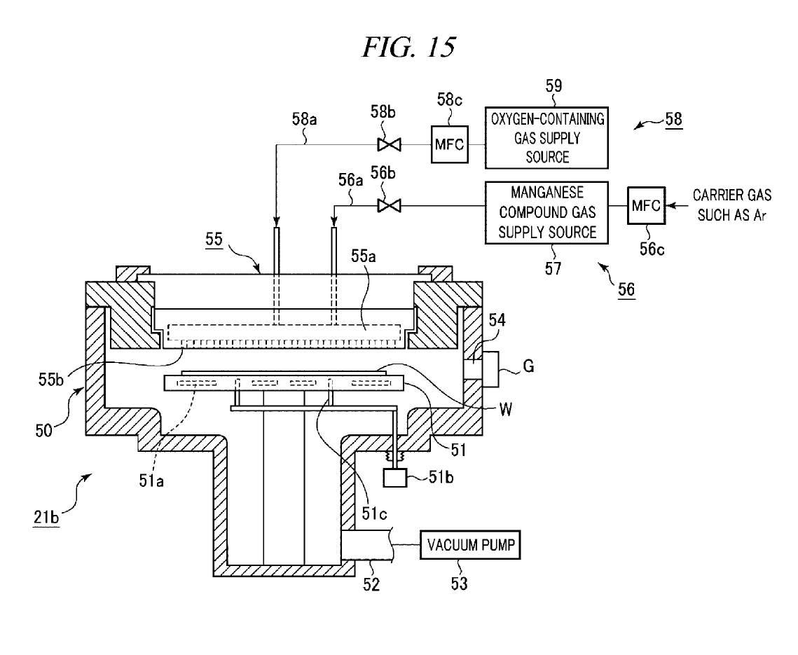

FIG. 14 is a plane view schematically illustrating an example of such a film forming system. In this example, the film forming system is described to be used in manufacturing a semiconductor device, and is configured to perform a film forming process on a silicon wafer (hereinafter, simply referred to as “wafer”) as a substrate. However, the example embodiment may not be limited to the formation of a manganese film on the wafer.

(Overall Configuration)

As shown in FIG. 14, a film forming system 100 includes a processing unit 20 configured to perform a process on a wafer W; a loading/unloading unit 30 configured to load/unload the wafer W into/from the processing unit 20; and a control unit 40 configured to control respective components of the film forming system 100. The film forming system 100 in accordance with the present example is configured as a cluster tool type (multi-chamber type) semiconductor manufacturing apparatus.

The processing unit 20 includes, in this example, four processing apparatuses (PM: Processing Modules) 21a to 21d configured to perform processes on the wafer W. The processing apparatuses 21a to 21d are configured to be depressurized to a preset vacuum level.

The processing apparatus 21a is configured to perform a pre-treatment on the wafer W, such as degassing by heating, configured to remove naturally oxidized copper by performing the hydrogen annealing process, configured to perform a plasma process, and configured to perform a surface modification of an underlying layer by ion irradiation, etc. Further, the processing apparatus 21b is configured to form a manganese oxide film of the present example embodiment on the wafer W in which the structure as shown in FIG. 2A is formed. The processing apparatus 21c is configured to perform a PVD process, typically, a sputtering process, for forming a copper wiring layer or a seed layer therefor. Further, the processing apparatus 21d is configured to perform an annealing process in a reducing atmosphere (or an inert gas atmosphere) for the silicification or the like. The processing apparatuses 21a to 21d are connected to a single transfer chamber (TM: Transfer Module) 22 via gate valves Ga to Gd, respectively.

The loading/unloading unit 30 includes a loading/unloading chamber (LM: Loader Module) 31. The loading/unloading chamber 31 is configured to control an internal pressure thereof to be an atmospheric pressure or a nearly atmospheric pressure, e.g., a positive pressure slightly higher than the exterior atmospheric pressure. As for the planar shape of the loading/unloading chamber 31, when viewed from the plane, the loading/unloading chamber 31 has a rectangular shape having two parallel long sides and short sides perpendicular to the long sides. One of the long sides of the loading/unloading chamber 31 is disposed adjacent to the processing unit 20. The loading/unloading chamber 31 includes load ports LP on which processing target substrate carriers C configured to accommodate therein wafers W are mounted. In the present example, three load ports 32a, 32b and 32c are provided at the other long side of the loading/unloading chamber 31 opposite to the long side disposed adjacent to the processing unit 20. However, the number of the load ports may be set as required. Each of the load port 32a to 32c is provided with a non-illustrated shutter. If a carrier C accommodating therein wafers W or an empty carrier C is mounted on one of the load ports 32a to 32c, the non-illustrated shutter is opened to communicate the inside of the carrier C with the inside of the loading/unloading chamber 31 while suppressing exterior air from entering thereinto.

For example, two load lock chambers (LLM: Load Lock Modules) 26a and 26b are provided between the processing unit 20 and the loading/unloading unit 30. Each of the load lock chamber 26a and 26b is configured to switch the inside atmosphere thereof between a preset vacuum atmosphere and an atmospheric pressure or a nearly atmospheric pressure. The load lock chambers 26a and 26b are connected via gate valves G3 and G4, respectively, to the side of the loading/unloading chamber 31 opposite to the side where the load ports 32a to 32c are provided. Further, the load lock chambers 26a and 26b are respectively connected to two sides of the transfer chamber 22 via gate valves G5 and 66, except the four sides thereof to which the processing apparatuses 21a to 21d are connected. By opening the corresponding gate valve G3 or G4, the load lock chambers 26a or 26b is allowed to communicate with the loading/unloading chamber 31, and by closing the corresponding gate valve G3 or G4, the load lock chamber 26a or 26b is blocked from the loading/unloading chamber 31. Further, by opening the gate valve G65 or 66, the load lock chamber 26a or 26b is allowed to communicate with the transfer chamber 22, and by closing the gate valve G65 or G66, the load lock chamber 26a or 26b is blocked form the transfer chamber 22.

A loading/unloading device 35 is provided within the loading/unloading chamber 31. The loading/unloading device 35 is configured to load/unload a wafer W into/from a processing target substrate carrier C and, also, to load/unload a wafer W into/from the load lock chambers 26a and 26b. The loading/unloading device 35 includes, for example, two multi-join arms 36a and 36b, and is configured to be movable on a rail 37 extended along a longitudinal direction of the loading/unloading chamber 31. Hands 38a and 38b are provided at leading ends of the multi-joint arms 36a and 36b, respectively. A wafer W is mounted on the hand 38a or 38b, and loading and unloading of the wafer W as described above is performed.

The transfer chamber 22 is configured as a vacuum vessel capable of maintaining therein a vacuum. A transfer device 24 configured to transfer a wafer W between the processing apparatuses 21a to 21d and the load lock chambers 26a and 26b is provided in the transfer chamber 22. The wafer W is transferred while isolated from the atmosphere. The transfer device 24 is positioned at an approximately central position of the transfer chamber 22. The transfer device 24 includes a single or a multiple number of transfer arms configured to be rotatable and extensible/contractible. In this example, the transfer device 24 includes two transfer arms 24a and 24b. Holders 25a and 25b are provided at leading ends of the transfer arms 24a and 24b, respectively. The wafer W is held on the holder 25a or 25h and transferred between the processing apparatuses 21a to 21d and the load lock chambers 26a and 26b, as stated above.

The control unit 40 includes a process controller 41, a user interface 42 and a storage unit 43. The process controller 41 includes a microprocessor (computer).

The user interface 42 includes a keyboard through which an operator inputs commands or the like to manage the film forming system 100, a display which visually displays an operational status of the film forming system 100, etc.

The storage unit 43 stores therein control programs for implementing various processes performed in the film forming system 100 under the control of the process controller 41 and processing recipes for performing a preset process in the film forming system 100 based on various data and processing conditions. The recipes are stored in a storage medium within the storage unit 43. The storage medium is computer-readable and may be implemented by, but not limited to, a hard disk or a portable memory device such as a CD-ROM, a DVD, a flash memory, or the like. Further, the recipes may be appropriately transmitted from another apparatus through, e.g., a dedicated line. A necessary recipe may be retrieved from the storage unit 43 in response to an instruction from the user interface 42 and executed by the process controller 41, so that a required process is performed on the wafer W under the control of the process controller 41.

(Film Forming Apparatus for Manganese Oxide Film)

Now, an example film forming apparatus of forming a manganese oxide film will be explained. In this example, the processing apparatus 21b of the film forming system 100 serves as the manganese oxide film forming apparatus. In the following, the processing apparatus 21b will be described as a manganese oxide film forming apparatus 21b.

FIG. 15 is a cross sectional view schematically illustrating an example of the manganese oxide film forming apparatus 21b. As depicted in FIG. 15, the manganese oxide film forming apparatus 21b includes a chamber 50. A mounting table 51 configured to mount thereon a wafer W horizontally is provided within the chamber 50. A heater 51a configured as a temperature controller for the wafer is provided within the mounting table 51. Further, the mounting table 51 has three elevating pins 51c (although only two are shown for the simplicity of illustration) configured to be moved up and down by an elevating device 51b. The wafer W is transferred between a non-illustrated wafer transfer device and the mounting table 51 via the elevating pins 51c.

One end of a gas exhaust line 52 is connected to a bottom of the chamber 50, and the other end of the gas exhaust line 52 is connected to a vacuum pump 53. A transfer opening 54 opened and closed by a gate valve G is provided in a sidewall of the chamber 50.

A gas shower head 55 is provided at a ceiling portion of the chamber 50, facing the mounting table 51. The gas shower head 55 includes a gas room 55a, and a gas supplied into the gas room 55a is introduced into the chamber 50 through a multiple number of gas discharge holes 55b.

The gas shower head 55 is connected to a manganese compound gas supply line system 56 configured to introduce a manganese compound gas into the gas room 55a. The manganese compound gas supply line system 56 includes a gas supply path 56a. Further, a valve 56b, a manganese compound gas supply source 57 and a mass flow controller 56c are connected to an upstream side of the gas supply path 56a. By way of non-limiting example, a bis (amide amino alkane) manganese compound gas may be supplied from the manganese compound gas supply source 57 by the bubbling method. An Ar gas or the like may be used as a carrier gas for the bubbling. This carrier gas may also be used as a purge gas.

Further, an oxygen-containing gas supply line system 58 configured to introduce an oxygen-containing gas into the gas room 55a is also connected to the gas shower head 55. The oxygen-containing gas supply line system 58 includes a gas supply path 58a. Further, an oxygen-containing gas supply source 59 is connected to an upstream side of the gas supply path 58a via a valve 58b and a mass flow controller 58c. By way of non-limiting example, a H₂O gas, a N₂O gas, a NO₂ gas, a NO gas, an O₂ gas, an O₃ gas, or the like may be supplied from the oxygen-containing gas supply source 59. Further, the oxygen-containing gas supply line system 58 is also configured to supply an Ar gas or the like as a purge gas.

In the present example embodiment, the manganese compound gas and the oxygen-containing gas are supplied into the processing chamber 50 through the gas discharge holes 55b after mixed in the gas room 55a of the gas shower head 55. However, the example embodiment may not be limited thereto. For example, a gas room for the manganese compound gas and a gas room for the oxygen-containing gas may be provided separately within the gas shower head 55, and the manganese compound gas and the oxygen-containing gas may be supplied into the chamber 50, individually.

In the manganese oxide film forming apparatus 21b configured as described above, a wafer W is loaded into the chamber 50 through the transfer opening 54 and mounted on the mounting table 51 which is controlled to have a preset temperature. Then, an ALD method is performed. In the ALD method, while adjusting the inside of the chamber 50 to a preset pressure, the supply of the manganese compound gas from the manganese compound gas supply line system 56 and the supply of the oxygen-containing gas from the oxygen-containing gas supply line system 58 are repeated multiple times while performing a purge of the chamber 50 therebetween. Through this ALD method, a manganese oxide film having a required thickness is formed. After the completion of the film formation, the processed wafer W is unloaded from the transfer opening 54.

<Other Applications>

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

By way of example, although a semiconductor substrate (semiconductor wafer), e.g., a silicon substrate is described as an example of a processing target substrate on which a manganese oxide film is to be formed, the processing target substrate may not be limited to the silicon substrate, but a glass substrate for use in the manufacture of a solar cell or a FPD may also be used.

Further, in the above-described example embodiment, the upper copper wiring layer is directly formed on the manganese oxide film. In the aspect of improving buriability, however, it may be possible to form a liner layer made of a ruthenium film on the manganese oxide film, and then, to form the upper copper wiring layer thereon.

We claim:

1. A manganese oxide film forming method of forming a manganese oxide film as a barrier film on a structure in which a lower copper wiring layer is formed on a substrate, a silicon-containing oxide film as an interlayer film is formed on the lower copper wiring layer, and a recess is formed in the silicon-containing oxide film to reach the lower copper wiring layer,
wherein the manganese oxide film is formed by an ALD process in which an adsorbing process of supplying and adsorbing a manganese compound gas onto the structure and a reacting process of supplying an oxygen-containing gas and reacting the adsorbed manganese compound gas with the oxygen-containing gas are repeatedly performed in a preset repetition number of times,
the manganese oxide film is controlled to have a thickness by adjusting the repetition number of times such that the manganese oxide film has a predetermined barrier property on the silicon-containing oxide film and copper buried in the recess has a preset resistance value on the exposed lower copper wiring layer.

2. The manganese oxide film forming method of claim 1,
wherein the repetition number of times is adjusted such that the thickness of the manganese oxide film on the silicon-containing oxide film has a range from about 1 nm to about 3.5 nm.

3. The manganese oxide film forming method of claim 1,
wherein the thickness of the manganese oxide film is a value converted from an atom number of manganese.

4. The manganese oxide film forming method of claim 1,
wherein the thickness of the manganese oxide film is equivalent to a value that allows a flat band voltage shift to be equal to or higher than about −0.2 V and equal to or lower than about 0.2 V on the silicon-containing oxide film and that allows an increment of the resistance value to be within about 1Ω on the lower copper wiring layer.

5. The manganese oxide film forming method of claim 1,
wherein the manganese compound gas is at least one selected from the group consisting of a cyclopentadienyl-based manganese compound, a carbonyl-based manganese compound, a β-diketone-based manganese compound, an amidinate-based manganese compound and an amide amino alkane-based manganese compound.

6. The manganese oxide film forming method of claim 1,
wherein the oxygen-containing gas is at least one selected from the group consisting of H₂O, N₂O, NO₂, NO, O₂, O₃, H₂O₂, CO, CO₂, alcohol, aldehyde, carboxylic acid, carboxylic acid anhydride, ester, organic ammonium salt, organic amine salt, organic amide, organic hydrazide.

7. The manganese oxide film forming method of claim 1,
wherein at least a part of the manganese oxide film on the silicon-containing oxide film is silicified.
